(19) United States
(12) Patent Application Publication
(10) Pub. No.: US 2025/0316972 A1
(43) Pub. Date: Oct. 9, 2025

(54) INTEGRATED GROUND FAULT DETECTION AND INTERRUPTER CIRCUIT WITH VARIABLE DELAY

(71) Applicant: Cypress Semiconductor Corporation, San Jose, CA (US)

(72) Inventors: Joseph HORANZY, Huntington Valley, PA (US); Nidhin MULANGATTIL SUDHAKARAN, Unterhaching (DE); James DAVIS, Blanco, TX (US)

(73) Assignee: Cypress Semiconductor Corporation, San Jose, CA (US)

(21) Appl. No.: 18/815,327

(22) Filed: Aug. 26, 2024

Related U.S. Application Data
(60) Provisional application No. 63/631,889, filed on Apr. 9, 2024.

(51) Int. Cl. H02H 3/02; H02H 3/10; H03F 3/45

(52) U.S. Cl. CPC H02H 3/021; H02H 3/10; H03F 3/45475

(57) ABSTRACT

An integrated circuit includes a transimpedance amplifier (TIA) coupled to a hot-to-ground (H/G) sensing coil. The H/G sensing coil is coupled to alternating current (AC) mains. The TIA converts a leakage current, received from the H/G sensing coil, to a leakage voltage. An analog-to-digital converter (ADC), coupled to the transimpedance amplifier, converts the leakage voltage to a digital signal. Control logic is coupled to the ADC and processes the digital signal to determine an average value associated with the leakage voltage over time and determines a trigger delay period corresponding to the average value. The control logic outputs, in response to the leakage voltage still satisfying the average value after waiting the trigger delay period, a trip signal to trip logic to cause a disconnect of a current supplied to a load by the AC mains.

### REFERENCE TO EARLIER FILED APPLICATION

This application claims the benefit under 35 U.S.C. § 119 (e) of U.S. Provisional Patent Application No. 63/631,889, filed Apr. 9, 2024, which is incorporated herein, in its entirety, by this reference.

### BACKGROUND

A ground fault circuit interrupter (GFCI) product or device operates by continuously monitoring the current flow in a sensing circuit. The current flow being monitored is often alternating-current (AC) from power mains. The GFCI device compares the current flowing into sensing circuit (through the hot wire) with the current flowing out of the sensing circuit (through the neutral wire). Under normal conditions, these currents are equal.

The GFCI device may contain a current transformer with two coils: one for the hot wire and one for the neutral wire. When the current flowing out of the sensing circuit does not match the current flowing in, which indicates a ground fault (e.g., a leakage of current to the ground), a difference is detected by the current transformer. If the difference exceeds a certain threshold (typically 4-6 milliamps), the sensing circuit triggers a response. In response to exceeding the threshold current, the sensing circuit activates a switch that quickly disconnects the power supply to the sensing circuit, stopping the flow of electricity. After tripping, the GFCI device is manually reset to restore power, ensuring the fault is corrected before the sensing circuit can be used again.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 is a schematic diagram of a ground fault circuit interrupter (GFCI) system in which sensing circuitry is implemented within an integrated circuit to detect a hot-to-ground (H/G) leakage current, according to at least one embodiment.

FIG. 2 is a schematic diagram illustrating a neural-to-ground (N/G) leakage path that is detectable using a combination of a N/G sensing coil and a H/G sensing coil, according to some embodiments.

FIG. 3 is a schematic diagram of a GFCI system in which sensing circuitry is implemented within an integrated circuit to detect a N/G leakage current, according to at least some embodiments.

FIG. 4 is a flowchart illustrating a method of operating the GFCI circuit of FIG. 1 according to some embodiments.

FIG. 5 is a flowchart illustrating a method of operating the GFCI circuit of FIG. 3 according to some embodiments.

### DETAILED DESCRIPTION

The following description sets forth numerous specific details such as examples of specific systems, components, methods, and so forth, in order to provide a good understanding of various embodiments of an integrated circuit configured to perform integrated ground fault detection and power interruption described herein. Such integrated circuits may be implemented within GFCI products or devices in various disclosed embodiments. In other instances, well-known components, elements, or methods are not described in detail or are presented in a simple block diagram format in order to avoid unnecessarily obscuring the subject matter described herein. Thus, the specific details set forth hereinafter are merely exemplary. Particular implementations may vary from these exemplary details and still be contemplated to be within the spirit and scope of the present embodiments.

Reference in the description to “an embodiment,” “one embodiment,” “an example embodiment,” “some embodiments,” and “various embodiments” means that a particular feature, structure, step, operation, or characteristic described in connection with the embodiment(s) is included in at least one embodiment. Further, the appearances of the phrases “an embodiment,” “one embodiment,” “an example embodiment,” “some embodiments,” and “various embodiments” in various places in the description do not necessarily all refer to the same embodiment(s).

The description includes references to the accompanying drawings, which form a part of the detailed description. The drawings show illustrations in accordance with exemplary embodiments. These embodiments, which may also be referred to herein as “examples,” are described in enough detail to enable those skilled in the art to practice the embodiments of the claimed subject matter described herein. The embodiments may be combined, other embodiments may be utilized, or structural, logical, and electrical changes may be made without departing from the scope and spirit of the claimed subject matter. It should be understood that the embodiments described herein are not intended to limit the scope of the subject matter but rather to enable one skilled in the art to practice, make, and/or use the subject matter.

Some ground fault circuit interrupter (GFCI) products on the market today are designed with a two-chip solution that includes an analog front end providing GFCI functionality and a microcontroller that executes safety functions to comply with the UL-943 specification, e.g., so that the GFCI products can be considered Class A devices. For example, the microcontroller is externally coupled to a GFCI analog device for purposes of performing self tests to conform with UL-943. This two-chip approach takes up printed circuit board (PCB) real estate, uses more components, and reduces reliability.

Further, many present GFCI designs employ hard-coded, arbitrary threshold values to determine when the circuit should trip open, e.g., interrupt or disconnect a load from alternating current (AC) power, during a current leakage event. If the sensing circuitry fails, present GFCI products have no contingency or backup circuit for protection that the GFCI product should provide. Further, in present GFCIs, false trips occur regularly due to lack of signal conditioning or filtering. In some cases, false nuisance trips cause end users to replace the GFCI device with a standard outlet, which is a less-safe, certainly non-ideal, solution.

Additionally, because present GFCI products are implemented in application-specific integrated circuit(s) (ASICs) or hardware, functionality cannot be altered after manufacturing. A new revision of the entire GFCI product or device would need to be implemented, which would cause delays in manufacturing.

Aspects and embodiments of the present disclosure overcome the above-mentioned and other deficiencies by integrating sensing circuitry on an integrated circuit (IC) with control logic, which is configured to analyze a digitized version of the leakage current (or voltage) and impose a delay on issuing a trip signal based on an average value associated with the leakage current/voltage. In some embodiments, the average value is a root mean square (RMS) or similarly averaged value of the digital signal over time. In this way, a customized delay can be employed depending on an averaged current or voltage value in order to avoid prematurely tripping a disconnect from power based on short variations in current that would otherwise cause a GFCI device, which employs a fixed threshold value, to trip.

For example, in some embodiments, a transimpedance amplifier is coupled to a hot-to-ground (H/G) sensing coil and the H/G sensing coil is coupled to alternating current (AC) mains. The transimpedance amplifier can convert a leakage current, received from the H/G sensing coil, to a leakage voltage. An analog-to-digital converter (ADC), coupled to the transimpedance amplifier, converts the leakage voltage to a digital signal. Further, in some embodiments, control logic is coupled to the ADC and configured to process the digital signal to determine an average value associated with the leakage voltage over time. The control logic can then determine a trigger delay period corresponding to the average value. The trigger delay period may be determined, for example, from a lookup table or the like stored in memory that indexes different trigger delay periods with different average values. The control logic can further output, in response to the leakage voltage still satisfying the average value after waiting the trigger delay period, a trip signal to trip logic, which causes a disconnect of a current supplied by the AC mains as will be explained. In embodiments, satisfying the average value means the leakage voltage is greater than or equal to the average value.

By way of further example, in additional or alternative embodiments, an oscillator is also coupled to a neutral to ground (N/G) sensing coil, which is coupled to the AC mains. In embodiments, the oscillator outputs an oscillating current to the AC mains in response to presence of a ground loop that couples the N/G sensing coil to a hot-to-ground (H/G) sensing coil, which is also coupled to the AC mains. The transimpedance amplifier is coupled between the H/G sensing coil and the oscillator and configured to trigger the oscillator into operation and convert the oscillating current into an oscillating voltage. In these embodiments, the ADC converts the oscillating voltage into a digital signal. Further, in embodiments, control logic, which is coupled to the ADC, processes the digital signal to determine an average value associated with the oscillating voltage over time. In embodiments, the control logic then determines a trigger delay period corresponding to the average value. The control logic can then output, in response to the oscillating voltage still satisfying the average value after waiting the trigger delay period, a trip signal to trip logic, which causes a disconnect of a current supplied by the AC mains, as will be explained. For example, the average of the oscillating voltage can be compared to the previously calculated average value to make this determination.

Advantages of the present disclosure include but are not limited to producing a GFCI product or device that is highly programmable for system enhancement and future requirements changes all while reducing part count and increasing system reliability. Additionally, the transimpedance amplifier and digital processing (performed by the control logic on the digitized voltage signal) can provide proper filtering before triggering to avoid causing nuisance trips. Further, the ability to calculate real-time RMS (or other type of average) current values enables handling variable trip delays depending on the actual leakage current, which works further to avoid nuisance trips. Other advantages will be apparent to those skilled in the art of GFCI-based design discussed hereinafter.

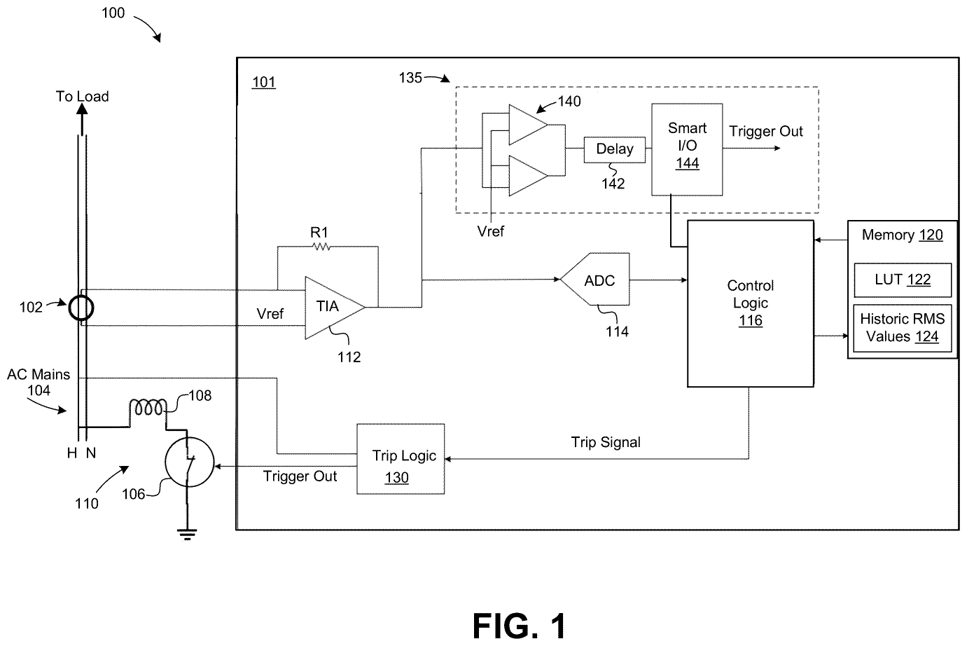

FIG. 1 is a schematic diagram of a ground fault circuit interrupter (GFCI) system 100 in which sensing circuitry is implemented within an integrated circuit 101 (e.g., GFCI circuit) to detect a hot-to-ground (H/G) leakage current, according to at least one embodiment. In some embodiments, the GFCI system 100 includes AC mains 104 having a hot line (H) and a neutral line (N) and an H/G sensing coil coupled to the AC mains to detect leakage current.

In some embodiments, the GFCI system 100 further includes a fault assembly 110 that includes a fault switch 106, which is coupled to a ground, and a solenoid 108 (or relay) that is coupled between the hot line of the AC mains 104 and the fault switch 106. The fault switch 106 can be triggered to disconnect AC power from a load coupled to the AC mains 104. In some embodiments, the fault switch 106 is a silicon controlled rectifier (SCR) or other kind of fault switch.

In at least some embodiments, the integrated circuit 101 includes a transimpedance amplifier 112 coupled to the H/G sensing coil 102. For example, each of two terminals of the H/G sensing coil 102 can be coupled to a respective input terminal of the transimpedance amplifier. The transimpedance amplifier 112 can include a resistor R1 coupled across a first input terminal and an output terminal, where a second input terminal receives a voltage reference signal. In embodiments, converts a leakage current, received from the H/G sensing coil 102, to a leakage voltage. The integrated circuit 101 can further include an analog-to-digital converter or ADC 114, coupled to the transimpedance amplifier 112, to convert the leakage voltage to a digital signal.

In various embodiments, the integrated circuit 101 further includes a control logic 116 coupled to the ADC 114 and to receive the digital signal. In embodiments, the control logic 116 processes the digital signal to determine an average value associated with the leakage voltage over time. In some embodiments, the average value is a root mean square (RMS) or similarly averaged value of the digital signal over time. Thus, the leakage voltage may occur over a period of time or intermittently over time. The control logic 116 can further determine a trigger delay period corresponding to the average value. The control logic 116 can further output, in response to the leakage voltage still satisfying the average value after waiting the trigger delay period, a trip signal to trip logic 130 to cause a disconnect of a current supplied to a load by the AC mains 104. By causing a delay of a particular trigger delay period, the integrated circuit 101 can mitigate any noise transients or false events within the trigger time. In other words, the leakage current will need to be sustained for at least the trigger delay period in order to trigger the trip logic 130 to disconnect the load from the AC mains 104.

In some embodiments, a memory is coupled to the control logic 116 to store a lookup table or LUT 122 (or similar data structure capable of storing data or information) and historic RMS values 124 (or other averaged values). In embodiments, the LUT 122 includes RMS values and corresponding trigger delay periods, e.g., indexed to the RMS values. Table 1 illustrates an example RMS voltage values (Vrms_ADC), the corresponding trigger delay (in milliseconds (ms)), as well as an original sensed current from the AC mains 104. Table 1 is exemplary only and an given LUT 122 can include more, fewer, and/or different values than those displayed in Table 1.

TABLE 1

| Sensed | | Trigger Delay |
|---|---|---|
| Current | Vrms_ADC | (mS) |
| 3.30E−02 | 2.1120 | 8.3333 |
| 2.90E−02 | 1.8480 | 8.3333 |
| 2.65E−02 | 1.6830 | 8.3333 |
| 2.25E−02 | 1.4190 | 16.6667 |
| 2.00E−02 | 1.2540 | 16.6667 |
| 1.75E−02 | 1.0890 | 25.0000 |
| 1.50E−02 | 0.9240 | 41.6667 |
| 1.00E−02 | 0.5940 | 58.3333 |
| 6.00E−03 | 0.3300 | 83.3333 |

In some embodiments, the control logic 116 calculates an RMS value as the average value. The control logic 116 can access the LUT 122 and determine, from the LUT 122, the trigger delay period based on the RMS value. The control logic 116 can then output the trigger signal after waiting the determined trigger delay period. In some embodiments, the control logic 116 can analyze the historical RMS values 124 stored in the memory 120 to determine a historical RMS value (or average value) to be compared against presently-measured RMS values from recent leakage current that is detected.

In some embodiments, the trip logic 130 is coupled to the fault switch 106 and to the AC mains 104. In embodiments, the trip logic 130 compares the current of the AC mains 104 to a minimum voltage during a positive half cycle of the current, e.g., the AC current from the AC mains 104. In embodiments, the minimum voltage is required to trip the solenoid 108 (or relay) coupled between the AC mains 104 and the fault switch 106. In embodiments, the trip logic 130 causes the fault switch 106 to close in response to the current exceeding the minimum threshold and in response to the trip signal. Once closed, the fault switch 106 applies a voltage to the solenoid 108 to energize the relay to disconnect the input AC line voltage (e.g., the voltage of the hot line of the AC mains 104) from the load.

In at least some embodiments, the integrated circuit 101 includes an optional backup circuit 135 to be employed should the control logic 116 fail or become defective. In some embodiments, the backup circuit 135 includes a pair of comparators 140, coupled to an output of the transimpedance amplifier 112. In embodiments, the pair of comparators 140 compares the leakage voltage to a predetermined threshold level (e.g., Vref) and outputs the trip signal if the leakage voltage exceeds the predetermined threshold level. The backup circuit 135 can further include a delay unit 142, coupled to the pair of comparators 140, to delay the trip signal by a predetermined delay.

In some embodiments, the backup circuit 135 further includes a smart I/O unit 144, which is coupled to the delay unit 142 and to the control logic 116. In embodiments, the smart I/O unit 144 monitors the control logic 116 for control logic failures and, responsive to detecting a control logic failure, outputs the trip signal to the fault switch 106 and switches from a GFCI mode, which employs the control logic 116, to an analog-only mode that employs hardware of the backup circuit 135. This can be accomplished by determining whether there is a presence of an operational signal (such as a heartbeat signal) from the control logic 116. The smart I/O unit 144 can switch the trip signal to come from the control logic 116 or engage output signals from the pair of comparators 140 to trip the fault switch 106 depending on how the leakage current compares to the predetermined threshold level required for triggering a disconnect from the AC mains.

In some embodiments, the integrated circuit 101 is a system on a chip (SoC) having on-board computing, e.g., in which the control logic 116 can be implemented with a microcontroller, a programmable processor, an ASIC, a field programmable gate-array (FPGA) device, a processing core, or the like. In embodiments, the memory 120 is volatile memory, non-volatile memory, or a combination of the volatile memory and non-volatile memory. Thus, the memory 120 can include memory storage that backs a cache in which is buffered the LUT 122 and the historic RMS values 124, e.g., to enable fast access to buffered values during operation of the integrated circuit 101 (e.g., GFCI circuit).

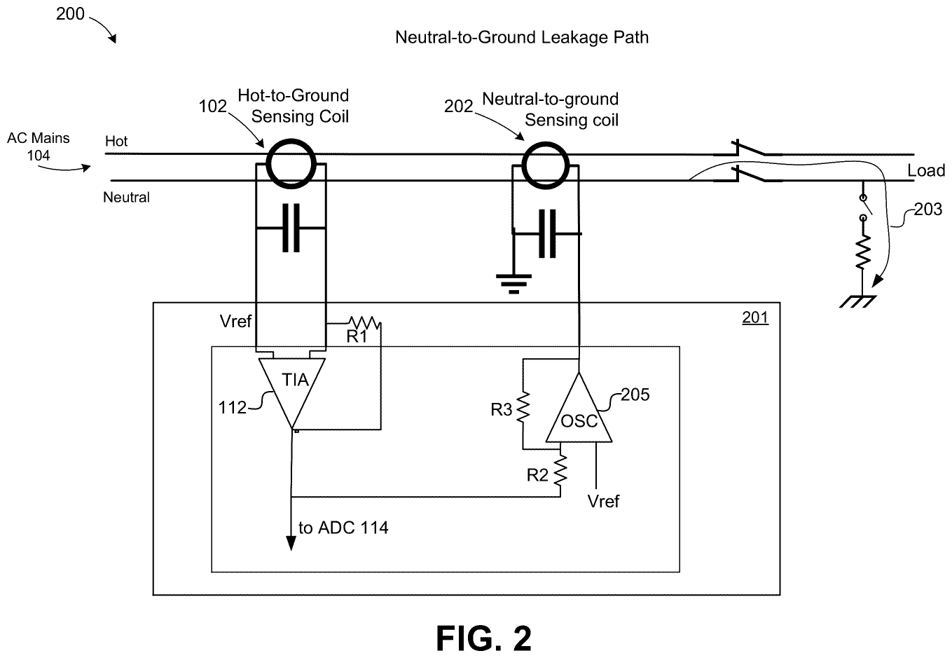

FIG. 2 is a schematic diagram illustrating a neural-to-ground (N/G) leakage path 200 that is detectable using a combination of a N/G sensing coil 202 and the H/G sensing coil 102, according to some embodiments. For example, in some embodiments, a neutral-to-ground (or N/G) leakage current 203 can occur in the presence of a ground loop that couples the N/G sensing coil 202 to the H/G sensing coil 102. As illustrated, this N/G leakage current 203 can flow from the neutral line (N) of the AC mains 104, which passes through the coupled coils, and then through a coupled load to ground, thus forming the “ground loop.”

In at least some embodiments, the system 100 can include an integrated circuit 201, which can be similar to the integrated circuit 101 of FIG. 1, that also includes an oscillator 205. In some embodiments, the oscillator 205 includes a first input terminal coupled to an output of the transimpedance amplifier 112 (e.g., via a second resistor, R2) and a second terminal that receives a reference voltage (Vref). A third resistor (R3) can be coupled between the first input terminal to an output terminal of the oscillator 205. In some embodiments, an output of the oscillator 205 is coupled to a first terminal of the N/G sensing coil 202. A second terminal of the N/G sensing coil 202 can be coupled to ground. In this way, when the ground loop is formed across the H/G sensing coil 102 and the N/G sensing coil 202, the output of the transimpedance amplifier 112 can trigger the oscillator 205 to detect a voltage that exceeds the reference voltage (Vref). Once triggered, the oscillator 205 can output an oscillating current to the AC mains 104 that can be used to detect a magnitude of the N/G leakage current 203, as will be explained in more detail. In some embodiments, the oscillator 205 produces the oscillating current at a frequency of at least two kilohertz.

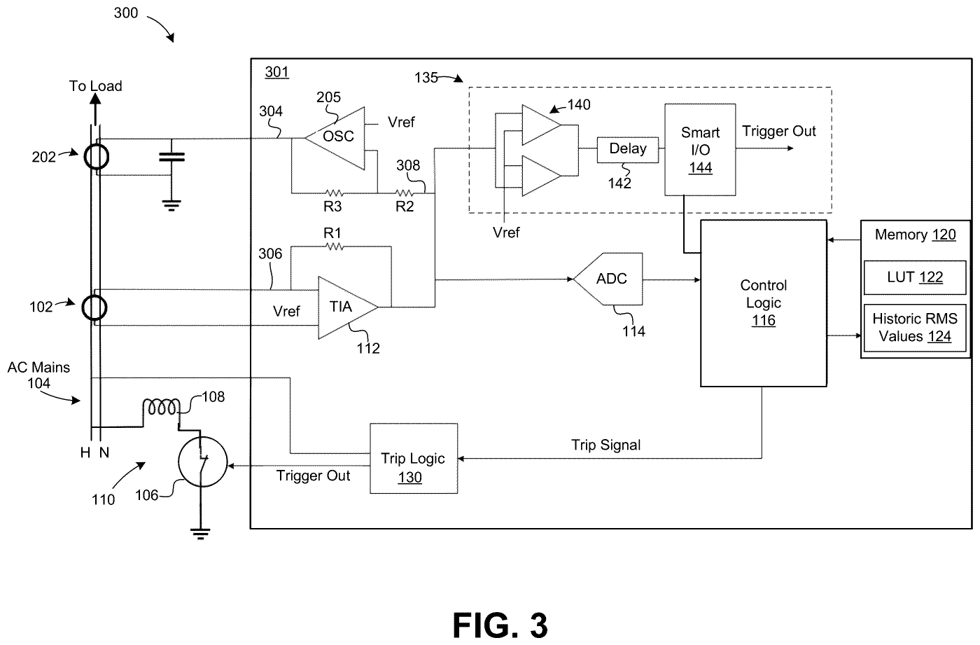

FIG. 3 is a schematic diagram of a GFCI system 300 in which sensing circuitry is implemented within an integrated circuit 301 to detect the N/G leakage current 203, according to at least some embodiments. In some embodiments, the integrated circuit 301 can be similar to the integrated circuit 201 of FIG. 2, but now illustrated also with the components discussed with reference to the integrated circuit 101 of FIG. 1.

In some embodiments, the oscillator 205 is coupled to the N/G sensing coil 202, which is coupled to AC mains 104. In embodiments, the oscillator 205 outputs an oscillating current to the AC mains 104 in response to presence of a ground loop that couples the N/G sensing coil 202 to the H/G sensing coil 102, which is also coupled to the AC mains 104. The transimpedance amplifier 112 can be coupled between the H/G sensing coil 102 and the oscillator 205. In embodiments, the transimpedance amplifier 112 triggers the oscillator 205 into operation and converts the oscillating current into an oscillating voltage, e.g., as discussed with reference to FIG. 2.

In various embodiments, as discussed, the ADC 114 is coupled to the transimpedance amplifier 112 and is configured to convert the oscillating voltage into a digital signal. The control logic 116 can be coupled between the ADC and the trip logic 130. In embodiments, the control logic 116 processes the digital signal to determine an average value associated with the oscillating voltage over time. In some embodiments, the average value is a root mean square (RMS) or similarly averaged value of the digital signal over time. Thus, the leakage voltage may occur over a period of time or intermittently over time. In embodiments, the control logic 116 determines a trigger delay period corresponding to the average value. The control logic can then output, in response to the oscillating voltage still satisfying the average value after waiting the trigger delay period, a trip signal to trip logic to cause a disconnect of a current supplied to a load by the AC mains 104. The rest of the functionality and description provided with reference to the integrated circuit 101 (FIG. 1) and the integrated circuit 201 (FIG. 2) equally apply to the integrated circuit 103 (FIG. 3) and will be not be repeated here.

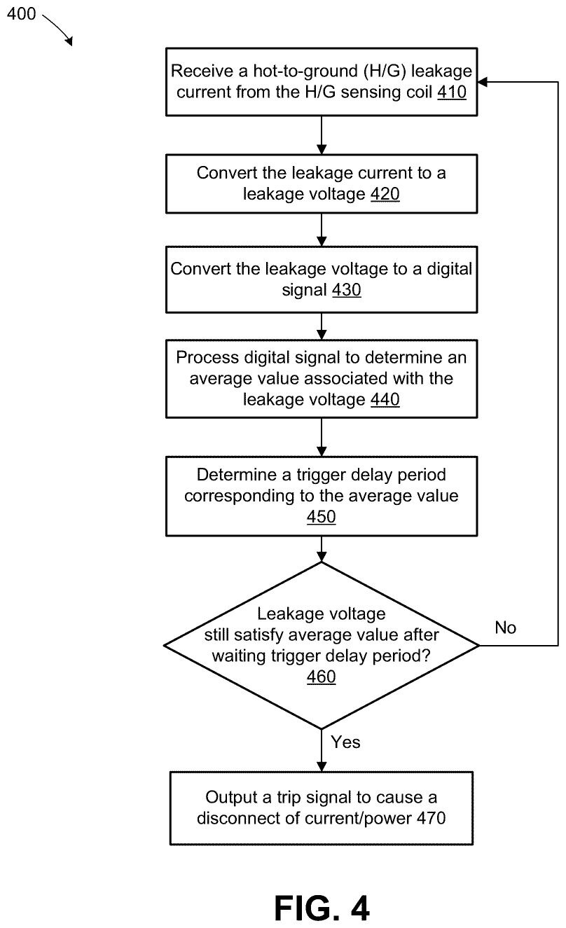

FIG. 4 is a flowchart illustrating a method 400 of operating the GFCI circuit of FIG. 1 according to some embodiments. The method 400 can be performed by the integrated circuit 101 discussed with reference to FIG. 1, to include processing logic that can include hardware (e.g., processing device, circuitry, dedicated logic, programmable logic, microcode, hardware of a device, integrated circuit, etc.), software (e.g., instructions run or executed on a processing device), or a combination thereof. Although shown in a particular sequence or order, unless otherwise specified, the order of the operations can be modified. Thus, the illustrated embodiments should be understood only as examples, and the illustrated operations can be performed in a different order, while some operations can be performed in parallel.

Additionally, one or more operations can be omitted in some embodiments. Thus, not all illustrated operations are required in every embodiment, and other process flows are possible.

At operation 410, the method includes the transimpedance amplifier 112 receiving a H/G leakage current from the H/S sensing coil.

At operation 420, the method 400 includes converting, by the transimpedance amplifier 112, a leakage current received from the H/G sensing coil to a leakage voltage.

At operation 430, the method 400 includes converting, by the ADC 114, the leakage voltage to a digital signal.

At operation 440, the processing logic processes the digital signal to determine an average value associated with the leakage voltage over time.

At operation 450, the processing logic determines a trigger delay period corresponding to the average value, e.g., by performing a lookup in the LUT 122.

At operation 460, the processing logic determines whether the leakage voltage still satisfies the average value after waiting the trigger delay period. If the leakage voltage does not, the method 400 can loop back to operation 410 and continue processing received H/G leakage current to determine whether triggering is appropriate, e.g., by performing operations 420-460 thereafter.

At operation 470, the processing logic outputs, in response to, at operation 460, the leakage voltage still satisfying the average value after waiting the trigger delay period, a trip signal to the trip logic 130 to cause a disconnect of a current supplied to a load by the AC mains.

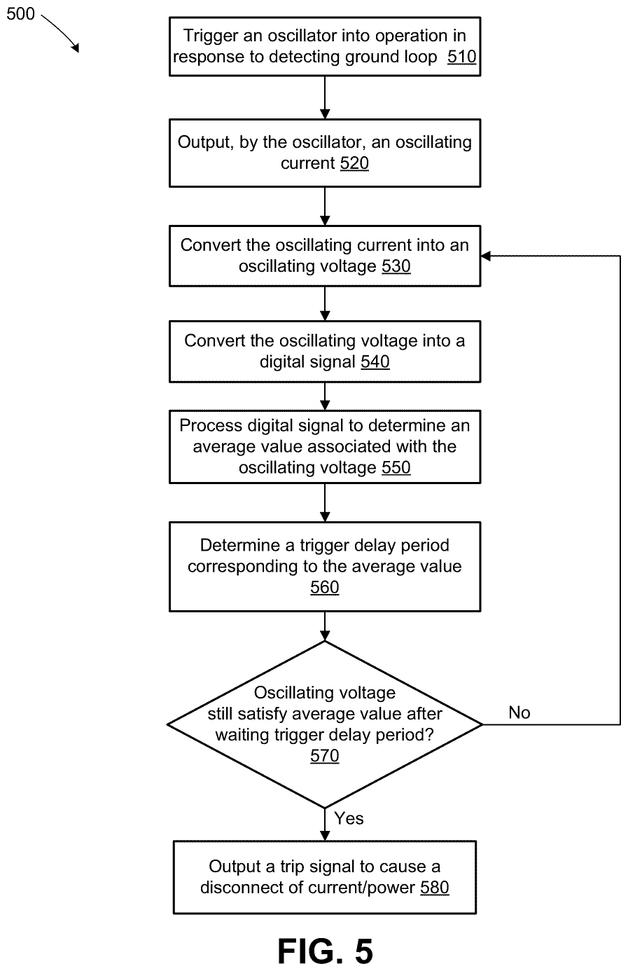

FIG. 5 is a flowchart illustrating a method 500 of operating the GFCI circuit of FIG. 3 according to some embodiments. The method 500 can be performed by the integrated circuit 301 discussed with reference to FIG. 3, to include processing logic that can include hardware (e.g., processing device, circuitry, dedicated logic, programmable logic, microcode, hardware of a device, integrated circuit, etc.), software (e.g., instructions run or executed on a processing device), or a combination thereof. Although shown in a particular sequence or order, unless otherwise specified, the order of the operations can be modified. Thus, the illustrated embodiments should be understood only as examples, and the illustrated operations can be performed in a different order, while some operations can be performed in parallel.

Additionally, one or more operations can be omitted in some embodiments. Thus, not all illustrated operations are required in every embodiment, and other process flows are possible.

At operation 510, the method 500 includes triggering, by the transimpedance amplifier 112, the oscillator 205 into operation in response to presence of a ground loop that couples the N/G sensing coil 202 to the H/G sensing coil 102.

At operation 520, the method 500 includes outputting, by the oscillator 205, an oscillating current in response to presence of the ground loop.

At operation 530, the method 500 includes converting, by the transimpedance amplifier 112, the oscillating current into an oscillating voltage.

At operation 540, the method includes converting, by the ADC 114, the oscillating voltage into a digital signal.

At operation 550, the processing logic processes the digital signal to determine an average value associated with the oscillating voltage over time.

At operation 560, the processing logic determines a trigger delay period corresponding to the average value, e.g., by performing a lookup in the LUT 122.

At operation 570, the processing logic determines whether the oscillating voltage still satisfies the average value after waiting the trigger delay period. If the oscillating voltage does not, the method 500 can loop back to operation 530 and continue converting the oscillating current into an oscillating voltage and performing operations 540-570 thereafter.

At operation 580, the processing logic outputs, in response to, at operation 570, the oscillating voltage still satisfying the average value after waiting the trigger delay period, a trip signal to the trip logic 130 to cause a disconnect of a current supplied to a load by the AC mains.

Various embodiments of integrating ground fault detection and interruption with a variable delay to AC power disconnection described herein may include various operations. These operations may be performed and/or controlled by hardware components, digital hardware and/or firmware, and/or combinations thereof. As used herein, the term “coupled to” may mean connected directly to or connected indirectly through one or more intervening components. Any of the signals provided over various on-die buses may be time multiplexed with other signals and provided over one or more common on-die buses. Additionally, the interconnection between circuit components or blocks may be shown as buses or as single signal lines. Each of the buses may alternatively be one or more single signal lines and each of the single signal lines may alternatively be buses.

Certain embodiments may be implemented by firmware instructions stored on a non-transitory computer-readable medium, e.g., such as volatile memory and/or non-volatile memory. These instructions may be used to program and/or configure one or more devices that include processors (e.g., CPUs) or equivalents thereof (e.g., such as processing cores, processing engines, microcontrollers, and the like), so that when executed by the processor(s) or the equivalents thereof, the instructions cause the device(s) to perform the described operations for GFCI-related architectures described herein. The non-transitory computer-readable storage medium may include, but is not limited to, electromagnetic storage medium, read-only memory (ROM), random-access memory (RAM), erasable programmable memory (e.g., EPROM and EEPROM), flash memory, or another now-known or later-developed non-transitory type of medium that is suitable for storing information.

Although the operations of the circuit(s) and block(s) herein are shown and described in a particular order, in some embodiments the order of the operations of each circuit/block may be altered so that certain operations may be performed in an inverse order or so that certain operation may be performed, at least in part, concurrently and/or in parallel with other operations. In other embodiments, instructions or sub-operations of distinct operations may be performed in an intermittent and/or alternating manner.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative sense rather than a restrictive sense.

What is claimed is:

1. An integrated circuit comprising:
a transimpedance amplifier coupled to a hot-to-ground (H/G) sensing coil, wherein the H/G sensing coil is coupled to alternating current (AC) mains, and wherein the transimpedance amplifier is to convert a leakage current, received from the H/G sensing coil, to a leakage voltage;
an analog-to-digital converter (ADC), coupled to the transimpedance amplifier, to convert the leakage voltage to a digital signal;
control logic coupled to the ADC, wherein the control logic is to:
process the digital signal to determine an average value associated with the leakage voltage over time;
determine a trigger delay period corresponding to the average value; and
output, in response to the leakage voltage still satisfying the average value after waiting the trigger delay period, a trip signal to trip logic to cause a disconnect of a current supplied to a load by the AC mains.

2. The integrated circuit of claim 1, wherein each of two terminals of the H/G sensing coil is coupled to a respective input terminal of the transimpedance amplifier.

3. The integrated circuit of claim 1, wherein the control logic is further to:
calculate a root mean square (RMS) value as the average value;
access a lookup table (LUT) comprising RMS values and corresponding trigger delay periods; and
determine, from the LUT, the trigger delay period based on the RMS value.

4. The integrated circuit of claim 3, wherein the integrated circuit comprises memory coupled to the control logic, wherein the control logic is to store the RMS value in the memory with historical RMS values.

5. The integrated circuit of claim 1, wherein the trip logic is coupled to a fault switch and to the AC mains, the trip logic to:
compare the current of the AC mains to a minimum voltage during a positive half cycle of the current, wherein the minimum voltage is required to trip a solenoid coupled between the AC mains and the fault switch; and
cause the fault switch to close in response to the current exceeding the minimum threshold and in response to the trip signal.

6. The integrated circuit of claim 1, wherein the integrated circuit further comprises:
a pair of comparators, coupled to an output of the transimpedance amplifier, wherein the pair of comparators is to:
compare the leakage voltage to a predetermined threshold level; and
output the trip signal if the leakage voltage exceeds the predetermined threshold level; and
a delay unit, coupled to the pair of comparators, to delay the trip signal by a predetermined delay.

7. The integrated circuit of claim 6, further comprising:
a smart I/O unit, coupled to the delay unit, wherein the smart I/O unit is to:
monitor the control logic for control logic failures; and
responsive to detecting a control logic failure:
output the trip signal to a fault switch; and
switch from a GFCI mode, which employs the control logic, to an analog-only mode.

8. An integrated circuit comprising:
an oscillator, coupled to a neutral to ground (N/G) sensing coil, which is coupled to alternating current (AC) mains, wherein the oscillator is to output an oscillating current to the AC mains in response to presence of a ground loop that couples the N/G sensing coil to a hot-to-ground (H/G) sensing coil, which is also coupled to the AC mains;
a transimpedance amplifier coupled between the H/G sensing coil and the oscillator, wherein the transimpedance amplifier is to trigger the oscillator into operation and convert the oscillating current into an oscillating voltage;
an analog-to-digital converter (ADC) coupled to the transimpedance amplifier, wherein the ADC is to convert the oscillating voltage into a digital signal;
control logic, coupled to the ADC, wherein the control logic is to:
process the digital signal to determine an average value associated with the oscillating voltage over time;
determine a trigger delay period corresponding to the average value; and
output, in response to the oscillating voltage still satisfying the average value after waiting the trigger delay period, a trip signal to trip logic to cause a disconnect of a current supplied to a load by the AC mains.

9. The integrated circuit of claim 8, wherein an output of the oscillator is coupled to a first terminal of the N/G sensing coil, and wherein a second terminal of the N/G sensing coil is coupled to ground.

10. The integrated circuit of claim 8, wherein the control logic is further to:
calculate a root mean square (RMS) value as the average value;
access a lookup table (LUT) comprising RMS values and corresponding trigger delay periods; and
determine, from the LUT, the trigger delay period based on the RMS value.

11. The integrated circuit of claim 10, wherein the integrated circuit comprises memory coupled to the control logic, wherein the control logic is to store the RMS value in the memory with historical RMS values.

12. The integrated circuit of claim 8, wherein the oscillator is to produce the oscillating current at a frequency of at least two kilohertz.

13. The integrated circuit of claim 8, wherein the trip logic is coupled to a fault switch and to the AC mains, the trip logic to:
compare the current of the AC mains to a minimum voltage during a positive half cycle of the current, wherein the minimum voltage is required to trip a solenoid coupled between the AC mains the fault switch; and
cause the fault switch to close in response to the current exceeding the minimum threshold and in response to the trip signal.

14. The integrated circuit of claim 8, wherein the integrated circuit further comprises:
a pair of comparators, coupled to an output of the transimpedance amplifier, wherein the pair of comparators is to:
compare the oscillating voltage to a predetermined threshold level; and
output a trip signal if the oscillating voltage exceeds the predetermined threshold level; and
a delay unit, coupled to the pair of comparators, to delay the trip signal by a predetermined delay.

15. The integrated circuit of claim 14, further comprising:
a smart I/O unit, coupled to the delay unit, wherein the smart I/O unit is to:
monitor the control logic for control logic failures; and
responsive to detecting a control logic failure:
output the trip signal to a fault switch; and
switch from a GFCI mode, which employs the control logic, to an analog-only mode.

16. A method of operating a ground fault circuit interrupter (GFCI) circuit, the GFCI circuit comprising a transimpedance amplifier coupled to a hot to ground (H/G) sensing coil, the H/G sensing coil coupled to alternating current (AC) mains, an analog-to-digital converter (ADC) coupled to the transimpedance amplifier, control logic coupled to the ADC and to trip logic, wherein the method of operating the GFCI circuit comprises:
converting, by the transimpedance amplifier, a leakage current received from the H/G sensing coil to a leakage voltage;
converting, by the ADC, the leakage voltage to a digital signal;
processing, by the control logic, the digital signal to determine an average value associated with the leakage voltage over time;
determining a trigger delay period corresponding to the average value; and
outputting, by the control logic, in response to the leakage voltage still satisfying the average value after waiting the trigger delay period, a trip signal to the trip logic to cause a disconnect of a current supplied to a load by the AC mains.

17. The method of claim 16, wherein operating the GFCI circuit further comprises:
calculating, by the control logic, a root mean square (RMS) value as the average value;
accessing, by the control logic, a lookup table (LUT) comprising RMS values and corresponding trigger delay periods; and
determining, from the LUT, the trigger delay period based on the RMS value.

18. The method of claim 16, wherein the trip logic is coupled to a fault switch and to the AC mains, and wherein operating the GFCI circuit further comprises:
comparing, by the trip logic, the current of the AC mains to a minimum voltage during a positive half cycle of the current, wherein the minimum voltage is required to trip a solenoid coupled between the AC mains and the fault switch; and
causing, by the trip logic, the fault switch to close in response to the current exceeding the minimum threshold to the trip signal.

19. A method of operating a ground fault circuit interrupter (GFCI) circuit, the GFCI circuit comprising an oscillator coupled to a neutral to ground (N/G) sensing coil, the N/G sensing coil coupled to alternating current (AC) mains, a hot-to-ground (H/G) sensing coil coupled to the AC mains, a transimpedance amplifier coupled between the oscillator and the H/G sensing coil, an analog-to-digital converter (ADC) coupled to the transimpedance amplifier, control logic coupled to the ADC, and trip logic coupled to the control logic, wherein the method of operating the GFCI circuit comprises:
triggering, by the transimpedance amplifier, the oscillator into operation in response to presence of a ground loop that couples the N/G sensing coil to the H/G sensing coil;
outputting, by the oscillator, an oscillating current in response to presence of the ground loop;
converting, by the transimpedance amplifier, the oscillating current into an oscillating voltage;
converting, by the ADC, the oscillating voltage into a digital signal;
processing, by the control logic, the digital signal to determine an average value associated with the oscillating voltage over time;
determining a trigger delay period corresponding to the average value; and
outputting, by the control logic, in response to the oscillating voltage still satisfying the average value after waiting the trigger delay period, a trip signal to trip logic to cause a disconnect of a current supplied to a load by the AC mains.

20. The method of operating the GFCI circuit of claim 19, wherein operating the GFCI circuit further comprises:
calculating, by the control logic, a root mean square (RMS) value as the average value;
accessing, by the control logic, a lookup table (LUT) comprising RMS values and corresponding trigger delay periods; and
determining, from the LUT, the trigger delay period based on the RMS value.
